(19) United States
(12) Patent Application Publication
(10) Pub. No.: US 2012/0092845 A1
(43) Pub. Date: Apr. 19, 2012

(54) ELECTRONIC DEVICE AND METHOD FOR UPGRADING ELECTROSTATIC DISCHARGE PROTECTION CAPABILITY OF ELECTRONIC DEVICE

(76) Inventor: Yi-Shyuan LEE, Yilan (TW)

(21) Appl. No.: 13/021,269

(22) Filed: Feb. 4, 2011

(30) Foreign Application Priority Data
Oct. 18, 2010 (TW) 099135375

(51) Int. Cl. H05K 7/00

(52) U.S. Cl. 361/807

(57) ABSTRACT

An electronic device and a method for upgrading electrostatic discharge protection capability of an electronic device are provided. The electronic device comprises a housing, an internal circuit and a plurality of screws each having an appendage. The screw has an upper surface, a lower surface and a threaded shaft portion. The lower surface connects the threaded shaft portion. The lower surface has an appendage. When the screw is screwed into the housing, the appendage destroys an insulating layer on the housing so that the housing electrically connects with a ground portion of the internal circuit.

### FIELD OF THE INVENTION

The present invention relates to an electronic device with screws having appendages, and more particularly to a method and an electronic device using screws having appendages to upgrade electrostatic discharge protection capability thereof.

### DESCRIPTION OF THE PRIOR ART

Electronic products, particularly for hand-held electronic products such as mobile phones, digital cameras, digital video cameras, mp3 players and personal digital assistances (PDA) are usually equipped with a variety of input/output ports in order to meet the requirements of increasing functions of the electronic products and decreasing sizes of the electronic products. While the internal circuits of the electronic products transmit data and signals through the input/output ports, possible electrostatic discharge phenomena may occur to damage the internal circuits and to destroy the functions of the electronic products.

In order to protect the internal circuit and to prevent from electronic products' damage described above, specific designs for electrostatic discharge protection are applied on the electronic products, as well as additional process procedures during manufacture. The purpose of the electrostatic discharge protection is to improve the reliability of the electronic products.

One of the conventional methods for upgrading the electrostatic discharge protection is to increase the volume or capacity of the electronic products through connecting the internal circuits to a housing of the electronic products. However, since the housing are treated anodizing to prevent from being oxidized, the housing will not be electrical conductive. Thus the locations of screws on the housing used to secure and mount the housing are through laser treatment to remove the anodizing layer on the housing to increase the volume or capacity for electrostatic discharge protection of the electronic products. The number of the locations of screws on the housing through laser treatment depends on the requirement of electrostatic discharge protection and the characteristics of the electronic products. However, additional laser treatment will increase the cost of the manufacture of the electronic product.

Therefore, present electronic products have structural drawbacks and are inconvenient to use and need to be improved. In order to solve the issues set forth, people have continuously tried various methods but fail to complete suitable design to solve the problems. The solutions of these issues apparently are long-felt needs since no suitable design and method can solve the problems mentioned above. Thus providing a method and an electronic device using screws having appendages to upgrade electrostatic discharge protection capability thereof and to reduce production cost and time is a major objective and goal for associated manufacturers.

### SUMMARY OF THE INVENTION

It is an object of the present invention to overcome the drawbacks of the present electronic products by providing a method and an electronic device using screws having appendages. The step of removing the insulating layer of a housing of the electronic device during the assembly of the electronic device can be omitted and electrostatic charges generated in the electronic device can be released from the ground layer of the internal circuit to the housing via the screw so that the volume or capacity for electrostatic discharge protection or grounding are increased and the production cost and time can also be reduced.

According to the object of the present invention, one embodiment of the invention provides an electronic device with screws having appendages. The electronic device comprises a housing, an internal circuit and a plurality of screws each having an appendage. Each the screw has an upper surface, a lower surface and a threaded shaft portion, the lower surface has an appendage thereon and connects the threaded shaft portion, when the screw is screwed into the housing, the appendage destroys an insulating layer on the housing so that the housing electrically connects with a ground portion of the internal circuit.

According to another object of the present invention, one embodiment of the invention provides a method for upgrading electronic discharge protection capability of an electronic device. The method comprises the following steps. First of all, an electronic device having a housing and an internal circuit and a plurality of screws each having an appendage are provided, each the screw has an upper surface, a lower surface and a threaded shaft portion, the lower surface has an appendage thereon and connects the threaded shaft portion. Then the screw is drove into the housing so that the appendage destroys an insulating layer on the housing and the housing electrically connects with a ground portion of the internal circuit.

Comparing to the conventional arts, the invention has the following advantages and benefits. The invention utilizes screws having appendages in an electronic device and the assembly thereof so that the step of removing the insulating layer of the housing of the electronic device during the assembly of the electronic device can be omitted and electrostatic charges generated in the electronic device can be released from the ground layer of the internal circuit to the housing via the screw. Thus the volume or capacity for electrostatic discharge protection or grounding are increased and the production cost and time can also be reduced.

As mentioned above, the invention is related to a method and an electronic device using screws having appendages. The electronic device comprises a housing, an internal circuit and a plurality of screws each having an appendage. Each the screw has an upper surface, a lower surface and a threaded shaft portion, the lower surface has an appendage thereon and connects the threaded shaft portion, when the screw is screwed into the housing, the appendage destroys an insulating layer on the housing so that the housing electrically connects with a ground portion of the internal circuit. The invention further provides a method using screws having appendages for upgrading electronic discharge protection capability of an electronic device. The step of removing the insulating layer of the housing of the electronic device during the assembly of the electronic device can be omitted and electrostatic charges generated in the electronic device can be released from the ground layer of the internal circuit to the housing via the screw so that the volume or capacity for electrostatic discharge protection or grounding are increased and the production cost and time can also be reduced.

In order to further describe the technological means and advantages of the present invention which are used to achieve the purposes of the invention, the practical means, structure, features and advantages of the method and electronic device using screws having appendages to upgrade electrostatic discharge protection capability thereof are described in the following contents with the attached drawings and preferred embodiments. The invention presents obvious technological improvement and is a new, progressive and practical design.

The description mentioned above is merely a schematic technological description. In order to render those with ordinary skill in the art more clear to make use and practice the invention according to the specification thereof, and to realize the above-mentioned objectives, features and advantages of the invention more easily, the following preferred embodiments accompanying with the drawings are described in detail.

### BRIEF DESCRIPTION OF THE DRAWINGS

The accompanying drawings illustrate various embodiments of the present invention and are a part of the specification. The illustrated embodiments are merely examples of the present invention and do not limit the scope of the invention.

FIGS. 1A and 1B show a schematic view of a screw having an appendage used in an electronic device according to one embodiment of the invention.

FIG. 1C shows a schematic view of a screw having an appendage used in an electronic device according to another embodiment of the invention.

FIG. 1D and FIG. 1E are bottom views of two embodiments of the screws shown in FIG. 1C respectively.

FIG. 1F and FIG. 1G show schematic views of screws each having an appendage used in an electronic device according to two embodiments of the invention respectively.

FIG. 2 shows a partial cross sectional view of a screw having an appendage screwed into an electronic device according to one embodiment of the invention.

FIG. 3 shows a partial schematic view of a screw having an appendage used in an electronic device according to one embodiment of the invention.

### DESCRIPTION OF THE PREFERRED EMBODIMENT

In order to further describe the technological means and advantages of the present invention which are used to achieve the purposes of the invention, the practical means, structure, features and advantages of the method and electronic device using screws having appendages to upgrade electrostatic discharge protection capability thereof are described in the following contents with the attached drawings and preferred embodiments.

The detailed description of the present invention will be discussed in the following embodiments, which are not intended to limit the scope of the present invention, but can be adapted for other applications. While drawings are illustrated in details, it is appreciated that the scale of each component may not be expressed exactly.

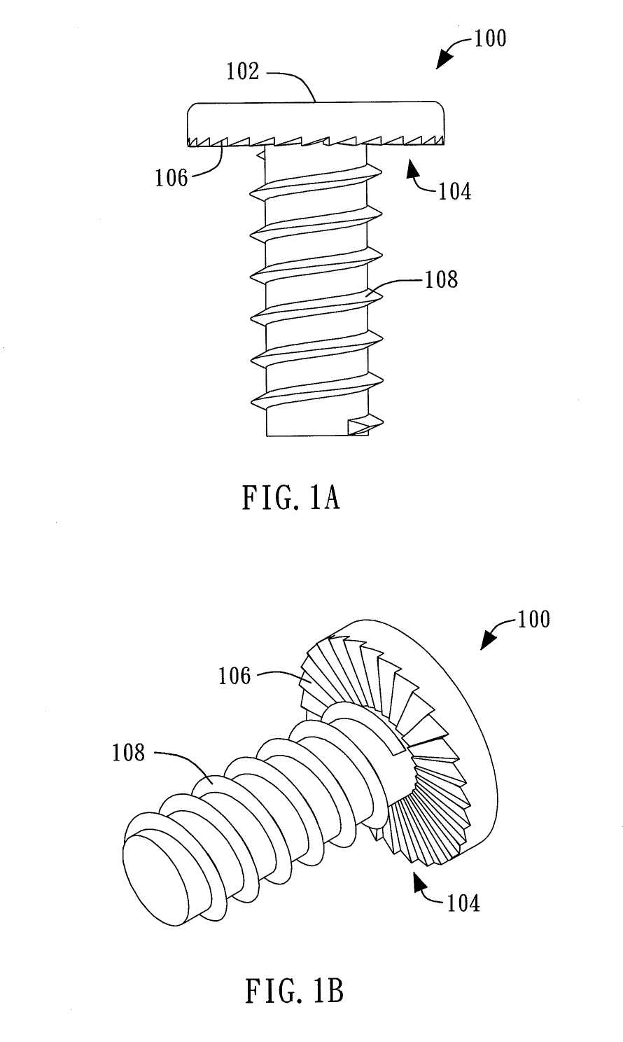

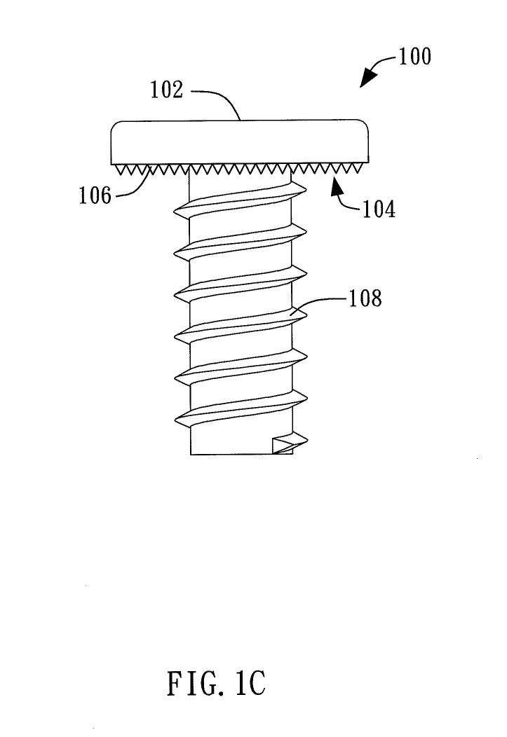

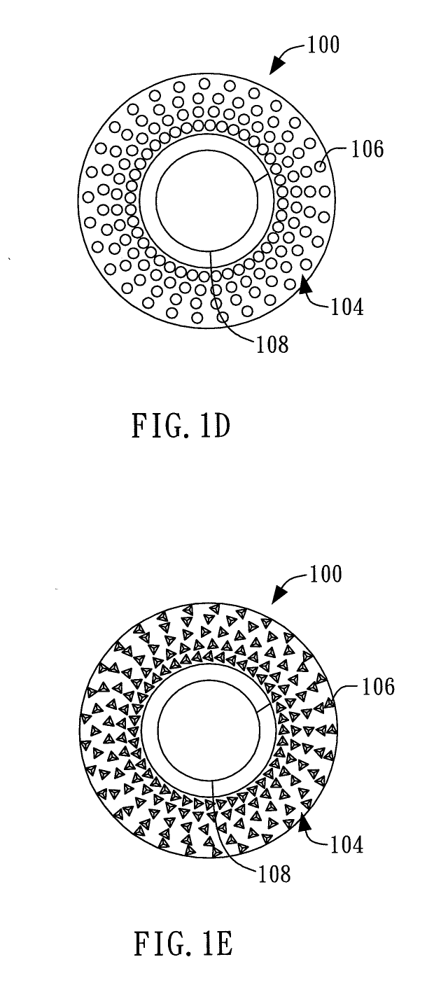

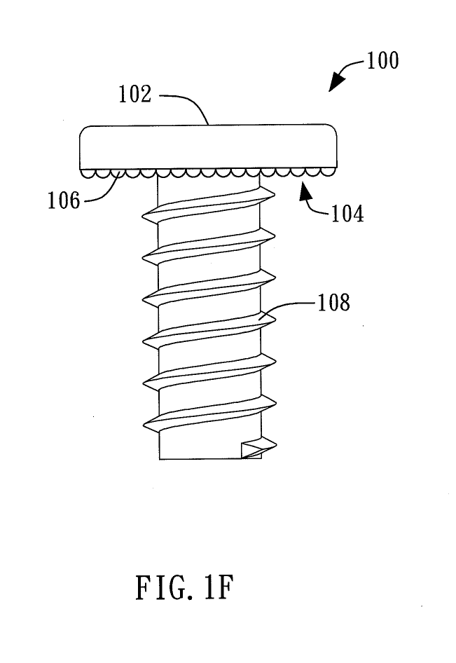

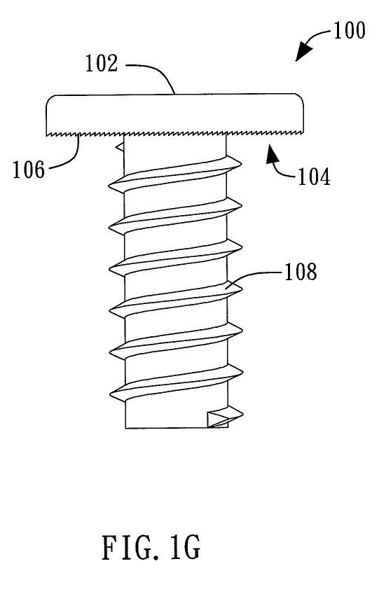

Referring to FIGS. 1A and 1B, a schematic view of a screw having an appendage used in an electronic device according to one embodiment of the invention. The screw 100 includes an upper surface 102, a lower surface 104 and a threaded shaft portion 108. The lower surface 104 connects to the threaded shaft portion 108, and the lower surface 104 has an appendage 106. When the screw 100 is screwed into a housing of the electronic device, such as metal cases or metal frames, but not limited to, the appendage 106 of the lower surface 104 may destroy an insulating layer which is applied on a surface of the housing. In this embodiment of the present invention, the appendage 106 comprises at least one embossed structure.

FIG. 1C shows a schematic view of a screw having an appendage used in an electronic device according to one embodiment of the invention. FIG. 1D and FIG. 1E are bottom views of two embodiments of the screws shown in FIG. 1C respectively. As shown in FIG. 1C, the appendage 106 of the lower surface 104 of the screw 100 includes at least one sharp tooth structure extending from the lower surface 104 and is parallel to the threaded shaft portion 108. When the screw 100 is screwed into the housing of the electronic device, the sharp tooth structure of the lower surface 104 of the screw 100 may destroy the insulating layer of the surface of the housing of the electronic device. Moreover, as shown in FIG. 1D, the sharp tooth structure includes a cone structure, wherein the cross sectional shape of the bottom includes a circle and an ellipse. Furthermore, as shown in FIG. 1E, the sharp tooth structure includes a triangular pyramid structure, wherein the cross sectional shape of the bottom includes, but not limited to, a triangle. The sharp tooth structure also can be a pyramid with a cross sectional shape of polygon.

FIG. 1F and FIG. 1G show schematic views of screws each having the appendage used in an electronic device according to two embodiments of the invention respectively. As shown in FIG. 1F, the appendage 106 includes at least one hemisphere structure which can rub the insulating layer of the surface of the housing of the electronic device by the arc contact surface of each hemisphere structure for removing or destroying the insulating layer when the screw 100 is screwed into the electronic device. Furthermore, as shown in FIG. 1G, the appendage 106 can be formed by sandblasting or grinding the lower surface 104 of the screw 100. The rough appendage on the lower surface 104 of the screw 100 can grind the insulating layer of the surface of the housing of the electronic device so as to the surface of the housing may be expose and to directly contact the screw 100 when the screw 100 is screwed into the electronic device. The appendage 106 of the lower surface 104 of the screw 100 can be combined of the above-mentioned embodiments. That is, the appendage 106 can be a combination of embossed structures, sharp tooth structures, hemisphere structures and rough structures which can be randomly placed or irregularly arranged. Nevertheless, such combination and arrangement are not limitation to the present invention.

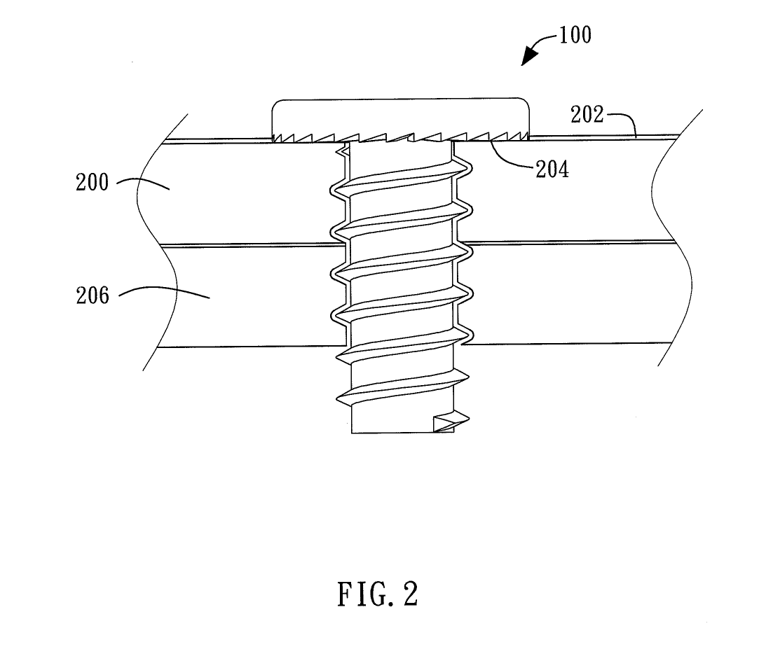

FIG. 2 shows a partial cross sectional view of a screw having an appendage screwed into an electronic device according to one embodiment of the invention. The screw 100 is screwed into a housing 200 and an internal structure 206 connecting to an internal circuit of the electronic device. The internal structure 206 comprises a metal frame of the electronic device for mounting and accommodating internal component modules or an internal circuit, but is not limited to the metal frame. For example, the internal structure 206 can connect to the ground terminal of the internal circuit. The housing 200 has a surface with an insulating layer 202. The insulating layer 202 includes an anodizing layer, but not limit to.

Referring to FIGS. 1A to 1E and FIG. 2, when the screw 100 is screwed into the housing 200, the appendage 106 of the lower surface 104 of the screw 100 may destroy the insulating layer 202 so that the appendage 106 can directly contact with the exposed metal surface 204 of the housing 200. The internal structure 206 electrically connects with the threaded shaft portion 108 of the screw 100 through the threaded hole of the internal structure 206, and the threaded shaft portion 108 electrically connects with the housing 200 through the appendage 106. Therefore, a ground layer or a ground terminal of the internal circuit of the electronic device can connect with the housing 200 through the screw 100. The static which may be generated in the electronic device can be released to the housing 200 via the screw 100 so that the damage of the static to electronic device may be reduced.

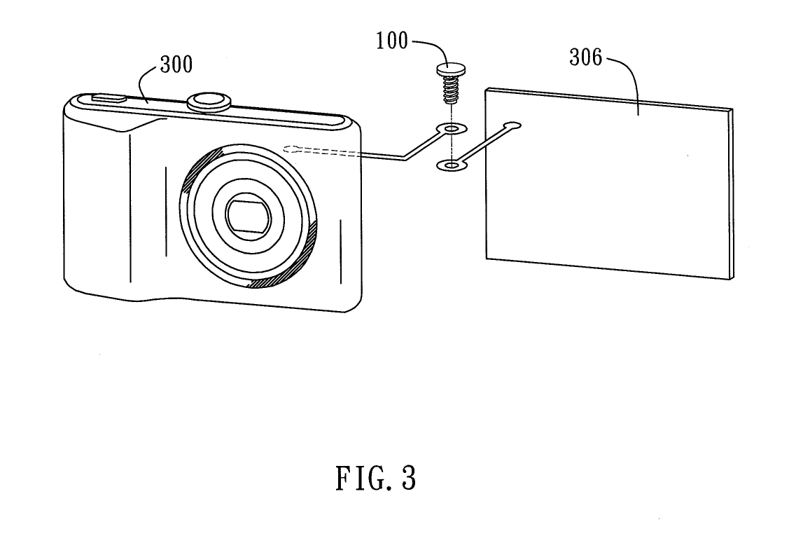

FIG. 3 shows a partial schematic view of a screw having an appendage used in an electronic device according to one embodiment of the invention. As shown in FIG. 3, a housing 300 of an electronic device electrically connects to a ground portion of an internal circuit of an electronic circuit board 306 of the electronic device through the screw 100. The internal circuit is on the electronic circuit board 306, and the ground portion includes a ground layer. As shown in FIG. 2, when the screw 100 is screwed into the housing 300, the appendage 106 of the screw 100 may destroy the insulating layer of the housing 300 so that the appendage 106 can contact with the exposed metal surface of the housing 300. Therefore, the ground layer or a ground terminal of the internal circuit of the electronic device can connect with the housing 300 through the screw 100. The static which may be generated in the electronic device can be released to the housing 300 via the screw 100 so that the volume or capacity for electrostatic discharge protection or grounding may be increased. The housing 300 comprises cases of the electronic device and a metal frame of the electronic device for mounting and accommodating internal components or an internal circuit. It is noted that FIG. 3 only shows a simplified schematic view and the embodiment of the electronic device shown includes a schematic configuration only, those features which are not crucial for one with ordinary skill in the art to make and use the invention are omitted. The features of the electronic apparatus of the embodiment which are omitted can be practiced via any well-known prior art, and one with ordinary skill in the art can make and use the invention based on ordinary level of skill. Although the housing 300 of the electronic device shown in FIG. 3 includes a case of a digital camera, but is not limited to, and the housing 300 is not limited to a metal case either. The housing 300 further comprises both cases and other metal frames or metal components mounted inside the metal cases. The ground portion of the internal circuit on the electronic circuit board 306 can electrically connect to the metal frame used to secure the electronic circuit board 306. The ground portion of the internal circuit on the electronic circuit board 306 can electrically connect to the housing 300 through the screw 100 so that the volume or capacity for electrostatic discharge protection or grounding are increased.

By using the screw having an appendage of the above-mentioned embodiment in the assembly of an electronic device can effectively increase the volume or capacity for electrostatic discharge protection or grounding and upgrade the capability of electrostatic discharge protection of an electronic device. In one embodiment, the invention provides a method for upgrading the capability of electrostatic discharge protection of an electronic device. By replacing conventional screws with the screw having an appendage, the locations of screws on the housing of the electronic device to be assembled do not need to be previously processed to remove any insulating layer or protecting layer. Instead, the screws with appendages on the lower surface thereof can be directly screwed into the threaded holes of the housing. During the process of driving the screw into the housing, the screw is drove by a torsion so that the appendage on the lower surface of the screw destroys and grinds the insulating layer of the housing. Since the screw is electrically conductive, the ground portion of the internal circuit of the electronic device can electrically connect to the housing through the screw so that the volume or capacity for electrostatic discharge protection or grounding are increased.

The invention applies screws having appendages to an electronic device and the assembly of the electronic device so that the step of removing the insulating layer of the housing of the electronic device during the assembly of the electronic device can be omitted. The screws with appendages on the lower surface thereof can be directly screwed into the threaded holes of the housing of the electronic device. Electrostatic charges generated in the electronic device can be released from the ground layer of the internal circuit to the housing via the screw so that the volume or capacity for electrostatic discharge protection or grounding are increased and the production cost and time can also be reduced.

Although specific embodiments have been illustrated and described, it will be appreciated by those skilled in the art that various modifications may be made without departing from the scope of the present invention, which is intended to be limited solely by the appended claims.

What is claimed is:

1. An electronic device comprising:
a housing and an internal circuit; and
a plurality of screws, each the screw having an upper surface, a lower surface and a threaded shaft portion, the lower surface having an appendage thereon and connecting the threaded shaft portion, when the screw is screwed into the housing, the appendage destroying an insulating layer on the housing so that the housing electrically connecting with a ground portion of the internal circuit.

2. The electronic device according to claim 1, wherein the appendage comprises at least one embossed structure.

3. The electronic device according to claim 1, wherein the appendage comprises at least one sharp tooth structure.

4. The electronic device according to claim 2, wherein the sharp tooth structure comprises a cone structure or a pyramid structure with a cross sectional shape of polygon.

5. The electronic device according to claim 1, wherein the appendage comprises at least one hemisphere structure.

6. The electronic device according to claim 1, wherein the appendage comprises at least one rough structure.

7. The electronic device according to claim 1, wherein the appendage comprises a combination of at least two selected from embossed structures, sharp tooth structures, hemisphere structures and rough structures.

8. The electronic device according to claim 7, wherein the embossed structures, the sharp tooth structures, the hemisphere structures or the rough structures are irregularly arranged.

9. The electronic device according to claim 1, wherein the insulating layer includes an anodizing layer.

10. The electronic device according to claim 1, wherein the internal circuit is on an electronic circuit board and the ground portion, and the ground portion includes a ground layer.

11. A method for upgrading electronic discharge protection capability of an electronic device, comprising:
providing an electronic device having a housing, an internal circuit and a plurality of screws, each the screw having an upper surface, a lower surface and a threaded shaft portion, the lower surface having an appendage thereon and connecting the threaded shaft portion; and
driving the screw into the housing so that the appendage destroying an insulating layer of the housing so that the housing electrically connecting with a ground portion of the internal circuit.

12. The method according to claim 11, wherein during the process of driving the screw into the housing, the screw is drove by a torsion so that the appendage of the lower surface of the screw destroys and grinds the insulating layer of the housing.

13. The method according to claim 11, wherein the screw is electrically conductive so that the housing electrically connects with the ground portion of the internal circuit through the screw.

14. The method according to claim 11, wherein the appendage comprises at least one embossed structure.

15. The method according to claim 11, wherein the appendage comprises at least one sharp tooth structure

16. The method according to claim 11, wherein the appendage comprises at least one hemisphere structure

17. The method according to claim 11, wherein the appendage comprises at least one rough structure.

18. The method according to claim 17, wherein the rough structure is formed by sandblasting or grinding.

19. The method according to claim 11, wherein the appendage comprises a combination of at least two selected from embossed structures, sharp tooth structures, hemisphere structures and rough structures.

20. The method according to claim 19, wherein the embossed structures, the sharp tooth structures, the hemisphere structures or the rough structures are irregularly arranged.
